(19) United States
(12) Patent Application Publication
(10) Pub. No.: US 2026/0128105 A1
(43) Pub. Date: May 7, 2026

(54) SEMICONDUCTOR DEVICES AND METHODS OF OPERATING THEREOF, SYSTEMS, AND COMPUTER-READABLE STORAGE MEDIA

(71) Applicant: Yangtze Memory Technologies Holding Co., Ltd., Wuhan (CN)

(72) Inventors: Yuanyuan MIN, Wuhan (CN); Wendong WANG, Wuhan (CN); Feng XU, Wuhan (CN); Lei JIN, Wuhan (CN); Zongliang HUO, Wuhan (CN); Jianquan JIA, Wuhan (CN)

(21) Appl. No.: 19/338,504

(22) Filed: Sep. 24, 2025

(30) Foreign Application Priority Data
Nov. 6, 2024 (CN) 202411579738.8

(51) Int. Cl. G11C 16/26; G11C 5/06; G11C 16/04; G11C 16/08; G11C 16/30

(52) U.S. Cl. CPC G11C 16/26; G11C 5/063; G11C 16/0483; G11C 16/08; G11C 16/30

(57) ABSTRACT

An example semiconductor device includes memory banks and a peripheral circuit. The peripheral circuit is configured to provide a first voltage to the bit line and sense a current on the bit line during a first read stage of a first memory bank and provide a second voltage to the bit line and sense a current on the bit line during a second read stage of a second memory bank. The first memory bank and the second memory bank are arranged along a direction from a first end of the bit line pointing to a second end of the bit line. The first end includes a node where the bit line is coupled to a page buffer or a bit line driver, The second voltage is greater than the first voltage, and/or a sense duration of the second read stage is greater than that of the first read stage.

### CROSS-REFERENCE TO RELATED APPLICATIONS

The present application claims the benefit of priority to China Application No. 202411579738.8, filed on Nov. 6, 2024, the content of which is incorporated herein by reference in its entirety.

### TECHNICAL FIELD

Examples of the present disclosure relate to the field of semiconductor technology, including but not limited to semiconductor devices, methods of operating a semiconductor device, and systems.

### BACKGROUND

In the classic Von Neumann computation architecture, a memory device and processor are separated, between which data is transmitted through a data bus. When executing a command, the processor first reads data from the memory device, processes it, and then writes the updated data back to the memory device. Frequent data movement brings huge power consumption and time overhead. In addition, due to the limited bandwidth of the memory device, the processing speed of the processor is limited by the access speed of the memory device, which greatly affects computing performance. With the rise of applications such as big data and artificial intelligence, the processing of massive amounts of data has made the bottleneck of Von Neumann computation architecture increasingly prominent.

### SUMMARY

According to a first aspect of examples of the present disclosure, a semiconductor device is provided, including: a plurality of memory banks; and a peripheral circuit coupled to the plurality of memory banks through a bit line. The peripheral circuit is configured to: provide a first voltage to the bit line and sense a current on the bit line during a first read stage of a first memory bank of the plurality of memory banks; and provide a second voltage to the bit line and sense a current on the bit line during a second read stage of a second memory bank of the plurality of memory banks, wherein the first memory bank and the second memory bank are arranged along a direction from a first end of the bit line pointing to a second end of the bit line, the first end is a node where the bit line is coupled to a page buffer or a bit line driver, the second read stage is different from the first read stage, and the second voltage is greater than the first voltage, and/or a sense duration of the second read stage is greater than a sense duration of the first read stage.

In some examples, the peripheral circuit includes: a voltage generation circuit configured to generate an initial voltage, wherein the initial voltage is greater than or equal to the second voltage; and a voltage regulation circuit coupled to the voltage generation circuit and the bit line, respectively, and configured to regulate the initial voltage to the first voltage during the first read stage and regulate the initial voltage to the second voltage during the second read stage.

In some examples, the voltage regulation circuit includes a variable resistor.

In some examples, the peripheral circuit includes a voltage generation circuit coupled to the bit line. The voltage generation circuit is configured to: generate the first voltage during the first read stage; and generate the second voltage during the second read stage.

In some examples, in a case where a sense duration of the second read stage is greater than a sense duration of the first read stage, a first reference current corresponding to the first read stage is greater than a second reference current corresponding to the second read stage.

In some examples, the peripheral circuit is further configured to: generate a first read result based on a sensed current on the bit line during the first read stage and the first reference current; and generate a second read result based on a sensed current on the bit line during the second read stage and the second reference current.

In some examples, the plurality of memory banks coupled to the bit line form a plurality of memory bank groups, wherein the first memory bank and the second memory bank are in different memory bank groups, respectively.

In some examples, the plurality of memory banks coupled to the bit line form a plurality of memory bank groups, wherein the first memory bank and the second memory bank are in the same memory bank group.

In some examples, the peripheral circuit is further configured to: apply corresponding input voltages to a plurality of first selection lines coupled to the first memory bank during the first read stage; and apply corresponding input voltages to a plurality of second selection lines coupled to the second memory bank during the second read stage.

In some examples, the semiconductor device includes a three-dimensional NAND memory device.

According to a second aspect of examples of the present disclosure, a method of operating a semiconductor device is provided, including: providing a first voltage to a bit line coupled to a plurality of memory banks and sensing a current on the bit line during a first read stage of a first memory bank of the plurality of memory banks; and providing a second voltage to the bit line and sensing a current on the bit line during a second read stage of a second memory bank of the plurality of memory banks, wherein the first memory bank and the second memory bank are arranged along a direction from a first end of the bit line pointing to a second end of the bit line, the first end is a node where the bit line is coupled to a page buffer or a bit line driver, the second read stage is different from the first read stage, and the second voltage is greater than the first voltage, and/or a sense duration of the second read stage is greater than a sense duration of the first read stage.

In some examples, the method further includes: generating an initial voltage, wherein the initial voltage is greater than or equal to the second voltage; regulating the initial voltage to the first voltage during the first read stage; and regulating the initial voltage to the second voltage during the second read stage.

In some examples, the method further includes: generating the first voltage during the first read stage; and generating the second voltage during the second read stage.

In some examples, in a case where a sense duration of the second read stage is greater than a sense duration of the first read stage, a first reference current corresponding to the first read stage is greater than a second reference current corresponding to the second read stage.

In some examples, the method further includes: generating a first read result based on a sensed current on the bit line during the first read stage and the first reference current; and generating a second read result based on a sensed current on the bit line during the second read stage and the second reference current.

In some examples, the plurality of memory banks coupled to the bit line form a plurality of memory bank groups, wherein the first memory bank and the second memory bank are in different memory bank groups, respectively.

In some examples, the plurality of memory banks coupled to the bit line form a plurality of memory bank groups, wherein the first memory bank and the second memory bank are in the same memory bank group.

In some examples, the method further includes: applying corresponding input voltages to a plurality of first selection lines coupled to the first memory bank during the first read stage; and applying corresponding input voltages to a plurality of second selection lines coupled to the second memory bank during the second read stage.

According to a third aspect of examples of the present disclosure, a semiconductor device is provided, including: a plurality of memory banks; and a voltage regulation circuit coupled to the plurality of memory banks through a bit line. The voltage regulation circuit is configured to: regulate an initial voltage to a first voltage and provide the first voltage to the bit line during a first read stage of a first memory bank of the plurality of memory banks; and regulate the initial voltage to a second voltage and provide the second voltage to the bit line during a second read stage of a second memory bank of the plurality of memory banks, wherein the first memory bank and the second memory bank are arranged along a direction from a first end of the bit line pointing to a second end of the bit line, the first end is a node where the bit line is coupled to a page buffer or a bit line driver, the second read stage is different from the first read stage, the initial voltage is greater than or equal to the second voltage, and the second voltage is greater than the first voltage.

In some examples, the semiconductor device further includes a voltage generation circuit coupled to the voltage regulation circuit. The voltage generation circuit is configured to generate the initial voltage and provide the initial voltage to the voltage regulation circuit.

In some examples, the voltage regulation circuit includes a variable resistor.

In some examples, the plurality of memory banks coupled to the bit line form a plurality of memory bank groups, wherein the first memory bank and the second memory bank are in different memory bank groups, respectively.

In some examples, the plurality of memory banks coupled to the bit line form a plurality of memory bank groups, wherein the first memory bank and the second memory bank are in the same memory bank group.

According to a fourth aspect of examples of the present disclosure, a system is provided, including: at least one semiconductor device as described in any of the first aspect of examples of the present disclosure or as described in any of the third aspect of examples of the present disclosure; and a controller coupled to the semiconductor device and configured to send input data to the semiconductor device and receive an operation result of the semiconductor device.

According to a fifth aspect of examples of the present disclosure, a computer-readable storage medium with a computer program stored thereon is provided, when executed by a processor, the computer program implements the method as described in any of the second aspect of examples of the present disclosure.

In examples of the present disclosure, by providing a first voltage to a bit line and sensing a current on the bit line during a first read stage of a first memory bank of a plurality of memory banks, and providing a second voltage to the bit line and sensing a current on the bit line during a second read stage of a second memory bank of the plurality of memory banks, wherein the second voltage is greater than the first voltage, and/or a sense duration of the second read stage is greater than a sense duration of the first read stage, the difference in voltage drop of the bit line among a plurality of memory banks coupled to the same bit line may be compensated, thereby improving accuracy of computing-in-memory.

### BRIEF DESCRIPTION OF THE DRAWINGS

In figures, unless otherwise specified, the same reference numbers that run through multiple figures represent the same or similar components or elements. These figures may not necessarily be drawn to scale. It should be understood that these figures only depict some examples disclosed in the present application and should not be construed as limiting the scope of the present application.

FIG. 1 is a schematic diagram of a semiconductor device according to an example.

FIG. 2 is a schematic diagram of a memory cell array according to an example.

FIG. 3 is a schematic diagram of a three-dimensional NAND memory cell array according to an example.

FIG. 4 is a schematic diagram of computing-in-memory using a three-dimensional NAND memory according to an example.

FIGS. 5a and 5b are schematic diagrams of a time-division operation of a plurality of memory banks coupled to a bit line according to an example.

FIG. 6 is a schematic diagram of a current distribution on a bit line according to an example.

FIG. 7 is a schematic diagram of a semiconductor device according to an example of the present disclosure.

FIG. 8a is a schematic diagram of a first read stage according to a first example of the present disclosure.

FIG. 8b is a schematic diagram of a second read stage according to a first example of the present disclosure.

FIG. 9 is a first schematic diagram of the voltage drop of a bit line according to different examples shown in the present disclosure.

FIG. 10a is a schematic diagram of a first read stage according to a second example of the present disclosure.

FIG. 10b is a schematic diagram of a second read stage according to a second example of the present disclosure.

FIG. 11 is a second schematic diagram of the voltage drop of a bit line according to different examples shown in the present disclosure.

FIG. 12 is a flowchart of a method of operating a semiconductor device according to an example of the present disclosure.

FIGS. 13a and 13b are schematic diagrams of providing the same voltage to a bit line at different time instances according to an example.

FIG. 14 is a three-dimensional schematic diagram of a semiconductor device according to an example of the present disclosure.

FIG. 15a is a schematic diagram of a first read stage according to a third example of the present disclosure.

FIG. 15b is a schematic diagram of a second read stage according to a third example of the present disclosure.

FIG. 16 is an operation timing diagram of a semiconductor device according to an example of the present disclosure.

FIG. 17a is a schematic diagram of a system according to a first example of the present disclosure.

FIG. 17b is a schematic diagram of a system according to a second example of the present disclosure.

FIG. 18a is a schematic diagram of an example memory card with a memory system according to an example of the present disclosure.

FIG. 18b is a schematic diagram of an example solid-state disk with a memory system according to an example of the present disclosure.

### DETAILED DESCRIPTION

For the convenience of understanding the present disclosure, examples of the present disclosure will be described in more detail below with reference to the relevant drawings. Although examples of the present disclosure are shown in the accompanying drawings, it should be understood that the present disclosure may be implemented in various forms and should not be limited by the examples described herein. Rather, providing these examples is to enable a more thorough understanding of the present disclosure and to fully convey the scope of the present disclosure to those skilled in the art.

In the following description, a large number of specific details are provided to provide a more thorough understanding of the present disclosure. However, it will be apparent to those skilled in the art that the present disclosure may be implemented without one or more of these details. In some examples, in order to avoid confusion with the present disclosure, some technical features known in the art are not described. That is, all the features of an actual implementation may not be described here, and the well-known functions and structures may not be described in detail.

Generally, a term may be understood at least partially from its usage in context. For example, depending at least in part on the context, the term “one or more” as used herein may be used to describe any feature, structure, or characteristic in a singular sense, or may be used to describe a combination of features, structures, or characteristics in a plural sense. Similarly, terms such as “a” or “the” may also be understood as conveying singular or plural usage, depending at least in part on the context. Additionally, terms “based on” may be understood as not necessarily intended to convey an exclusive set of factors, and may alternatively allow for an additional factor that is not described necessarily and explicitly, which also depends at least in part on the context.

Unless otherwise defined, the terms used herein are for the purpose of describing examples only and are not intended to be limiting of the present disclosure. When used herein, the singular forms of “a”, “an”, and “the/said” are also intended to include the plural form, unless the context clearly indicates otherwise. It should also be understood that the terms “compose” and/or “include”, when used in this specification, determine the presence of the described features, integers, operations, operations, elements, and/or components, but do not exclude the presence or addition of one or more additional features, integers, operations, operations, elements, components, and/or groups. When used herein, the term “and/or” includes any and all combinations of the listed related items.

In order to fully understand the present disclosure, detailed operations and structures will be presented in the following description to illustrate the technical solution of the present disclosure. The preferred examples of the present disclosure are described in detail below, however, the present disclosure may also have other examples in addition to these examples.

In order to solve the bottleneck of the classic Von Neumann computation architecture, the architecture of computing-in-memory chip has emerged. Its basic idea is to embed a computing function in a memory device and directly use the memory device for logical computing, thereby reducing the amount and distance of data transmission between a memory device and a processor, reducing power consumption meanwhile improving computing performance, and thus potentially building a computing system with high computing power, high bandwidth, and high energy efficiency.

The computing-in-memory chip have both storage and calculation capabilities based on its own physical characteristics. Storage capability refers to the ability of different memory devices to store numerical values by changing their conductance values based on their physical characteristics. Calculation capability refers to the ability to complete vector matrix multiplication calculations within a certain period of time by constructing an array of memory devices according to Ohm's law and Kirchhoff's law. The computing-in-memory chip includes but is not limited to: Static Random Access Memory (SRAM), Dynamic Random Access Memory (DRAM), and NAND flash memory. NAND flash memory is a non-volatile memory with a large capacity, making it a widely concerned object in the computing-in-memory chips. The following will provide an introduction to NAND flash memory related content.

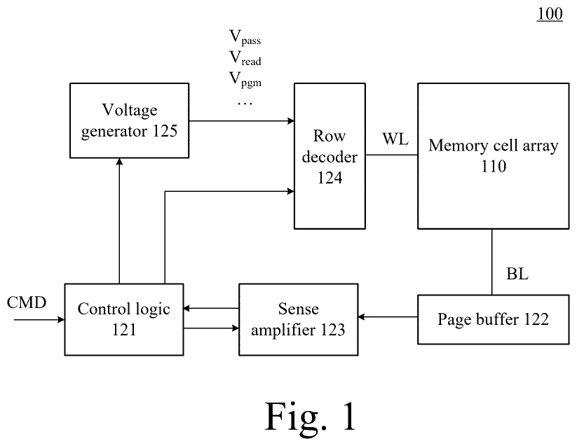

FIG. 1 is a schematic diagram of a semiconductor device according to an example. The semiconductor device includes but not limited to a three-dimensional NAND memory device. An example of the present disclosure will take a three-dimensional NAND memory device as an example for illustration.

Referring to FIG. 1, the semiconductor device 100 includes a memory cell array 110 and a peripheral circuit coupled to the memory cell array 110. The peripheral circuit may be coupled to the memory cell array 110 through a bit line (BL), a word line (WL), and other drive/select lines (not shown in FIG. 1). The peripheral circuit may include any suitable analog, digital, and mixed signal circuit for applying a voltage signal and/or a current signal to each target memory cell and sensing a voltage signal and/or a current signal from each target memory cell through a bit line (BL), a word line (WL), and other drive/select lines to facilitate operations of the memory cell array 110. The memory cell array 110 will be described in detail in the following and will not be repeated here.

The peripheral circuit may include a control logic 121, a page buffer 122, a sense amplifier 123, a row decoder 124, and a voltage generator 125. In some examples, the peripheral circuit may include various types of circuits formed using metal oxide semiconductor (MOS) technology. In some examples, an additional peripheral circuit not shown in FIG. 1 may also be included.

The page buffer 122 may be configured to read data from the memory cell array 110 and program (also known as write) data to the memory cell array 110 based on a control signal from the control logic 121. In one example, the page buffer 122 may store one page of programming data (write data) to be programmed into a physical page of memory cell array 110. In another example, the page buffer 122 may perform program validation operations to ensure that data has been correctly programmed into the memory cells coupled to the selected word line. In another example, the page buffer 122 may also sense a low-power signal from a bit line representing data bits stored in memory cells, and the sense amplifier 123 amplifies a small voltage swing to a recognizable logic level during a read operation. The page buffer 122 and the sense amplifier 123 may be configured to be controlled by the control logic 121.

The row decoder 124 may be configured to be controlled by the control logic 121, and to select/deselect a memory block of the memory cell array 110 and select/deselect a word line coupled to the memory block. The row decoder 124 may also be configured to drive the word line by using a word line voltage generated from the voltage generator 125. In some examples, the row decoder 124 may also select/deselect and drive the upper and lower select lines. As described in detail below, the row decoder 124 is configured to perform a programming operation on the memory cell coupled to the selected word line(s). The voltage generator 125 may be configured to be controlled by the control logic 121 and generate a word line voltage (e.g., program voltage V_{pgm}, read voltage V_{read}, pass voltage Vₚₐₛₛ, etc.) to be supplied to the memory cell array 110, and a bit line voltage and a source line voltage to be supplied to the memory cell array 110.

The control logic 121 may be coupled to each peripheral circuit described above and configured to control operations of each peripheral circuit. The register (not shown in the figure) may be coupled to the control logic 121 and include a status register, a command register, and an address register for storing status information, command opcodes, and command addresses used to control operations of each peripheral circuit. The interface (not shown in the figure) may be coupled to the control logic 121 and act as a control buffer to buffer a control command (CMD) received from a host (not shown in the figure) and relay it to the control logic 121, and buffer status information received from the control logic 121 and relay it to the host. The interface may also be coupled to a column decoder/bit line driver via a data bus and serve as a data I/O interface and data buffer to buffer data and relay it to the memory cell array 110 or buffer or relay data from the memory cell array 110.

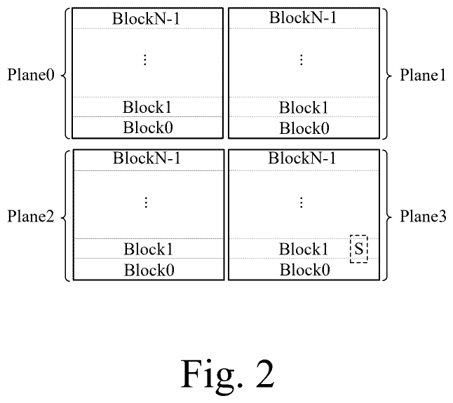

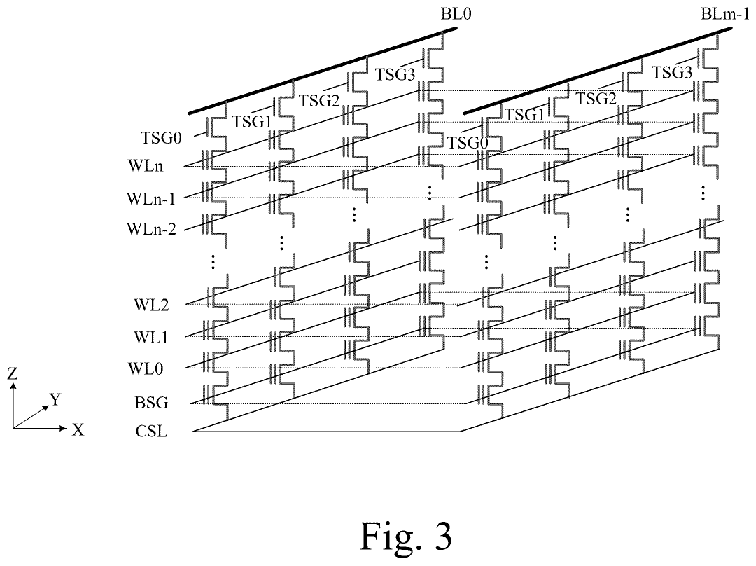

FIG. 2 is a schematic diagram of a memory cell array according to an example. Referring to FIG. 2, the memory cell array may include a plurality of memory planes, such as Plane0, Plane1, Plane2, and Plane3. Each memory plane includes a plurality of memory blocks, such as Block0, Block1, . . . , BlockN−1, wherein N is an integer greater than 1. In some examples, the number of memory planes is not limited to 4 shown in FIG. 2, and may also be other numbers, such as 1, 2, 8, etc. The number of memory blocks included in any two memory planes may be the same or different, and the present disclosure has no special restrictions on this. The memory cell array may include a three-dimensional NAND memory cell array. The following will provide an example explanation of the three-dimensional NAND memory cell array in the S region of FIG. 2, in connection with FIG. 3.

FIG. 3 is a schematic diagram of a three-dimensional NAND memory cell array according to an example, wherein the memory cell is a NAND memory cell, and the memory cell is provided in the form of an array of memory strings. Each memory string extends vertically and includes a plurality of memory cells coupled in series and stacked vertically. Each memory cell may maintain continuous analog values, such as voltage or charge, depending on the number of electrons trapped in the area of the memory cell. Each memory cell may be a floating gate type memory cell including a floating gate transistor, or a charge trapping type memory cell including a charge trapping transistor. For example, as shown in FIG. 3, each memory string includes a plurality of memory cells coupled in series and vertically stacked. A plurality of word lines are coupled to the corresponding memory cells, respectively, and the plurality of word lines are represented as WL0, WL1 . . . , WLn−1, WLn in FIG. 3, respectively, wherein n is an integer greater than 1. In practical applications, the number of memory cells and word lines is not limited to that shown in FIG. 3, and may also be other numbers.

In some examples, each memory cell is a Single Level Cell (SLC) that has two possible memory states and may therefore store one bit of data. For example, the first memory state ‘0’ may correspond to a first voltage range, and the second memory state ‘1’ may correspond to a second voltage range. In some examples, each memory cell is a multi-level cell capable of storing more than a single bit of data in four or more memory states, such as a Multi Level Cell (MLC) that stores two bits per cell, a Triple Level Cell (TLC) that stores three bits per cell, or a Quad Level Cell (QLC) that stores four bits per cell.

In some examples, each memory string may include a lower select transistor (also known as Bottom Select Gate, BSG) at its source terminal and an upper select transistor (also known as Top Select Gate, TSG) at its drain terminal. The lower select transistor and upper select transistor may be configured to activate the selected memory string during read and program operations. The sources of memory strings in the same memory block may be coupled through a Common Source Line (CSL). In other words, all memory strings in the same memory block have a common source (Array Common Source, ACS).

In some examples, the upper select transistor of each memory string is coupled to a corresponding bit line, and data may be read or written from the bit line via an output bus (not shown). For example, as shown in FIG. 3, the memory cell array may be coupled to the peripheral circuit through m bit lines, which are BL0, . . . , BLm−1, wherein m is an integer greater than 1. Each bit line is coupled to a plurality of memory strings arranged along the extension direction of the bit line. For example, as shown in FIG. 3, four memory strings arranged along the extension direction of the bit line are coupled to the same bit line, and the upper select transistors of these four memory strings are TSG0, TSG1, TSG2, and TSG3, respectively. In practical applications, the number of memory strings coupled to each bit line is not limited to that shown in FIG. 3, and may also be other numbers.

In some examples, each memory string is configured to be selected or deselected by applying a selection voltage (e.g., a voltage higher than the threshold voltage of the upper select transistor) or a deselection voltage (e.g., OV) to the corresponding upper select transistor through one or more upper select lines and/or by applying a selection voltage (e.g., a voltage higher than the threshold voltage of the lower select transistor) or a deselection voltage (e.g., OV) to the corresponding lower select transistor through one or more lower select lines.

In some examples, each memory string may include a bottom dummy transistor between its bottom memory cell and lower select transistor, and a top dummy transistor between its top memory cell and upper select transistor. The bottom dummy transistor of each memory string is coupled to the corresponding bottom dummy word line, and the top dummy transistor of each memory string is coupled to the corresponding top dummy word line. In practical applications, the number of bottom and top dummy transistors in each memory string is not limited to that shown in FIG. 3, and may also be other numbers.

In some examples, a memory string may be organized into a plurality of memory blocks as shown in FIG. 2, each of which may have a common source line. In some examples, each memory block is a basic data unit used for an erasing operation, meaning that all memory cells on the same memory block are erased simultaneously. To erase memory cells in a selected memory block, a common source line coupled to the selected memory block and unselected memory blocks in the same plane as the selected memory block may be biased with an erase voltage. In some examples, the erase operation may be performed at the level of a half memory block, at the level of a quarter memory block, or at the level of any suitable number of memory blocks or any suitable fraction of memory blocks. The memory cells of adjacent memory strings may be coupled through a word line, and the word line selects which row of memory cells is affected by read and program operations.

As shown in FIG. 1, when using a three-dimensional NAND memory device for operations, the control logic 121 may receive input data sent by the controller. The digital-to-analog conversion circuit (not shown in FIG. 1) converts the input data into a voltage signal that needs to be applied to a word line or bit line. The voltage generator 125 generates the corresponding voltage that needs to be applied to the word line or bit line. The row decoder 124 is configured to use the word line voltage generated from the voltage generator 125 to drive the selected word line, or the column decoder (not shown in FIG. 1) is configured to use the bit line voltage generated from the voltage generator 125 to drive the selected bit line. The analog operation result obtained after the operation is transmitted to the analog-to-digital conversion circuit through the page buffer 122 and column decoder. The analog-to-digital conversion circuit converts the analog operation result into a digital operation result and transmits the final digital operation result to the control logic 121.

For computing-in-memory chips, it is necessary to implement the multiplication operation or multiply-accumulate operation of input data and a weight matrix. The input data may be an input vector or matrix composed of a plurality of elements, and the weight matrix is composed of a plurality of weights. Each element in the input data needs to be multiply-accumulated with a plurality of weights in the weight matrix to obtain the corresponding element in the output data.

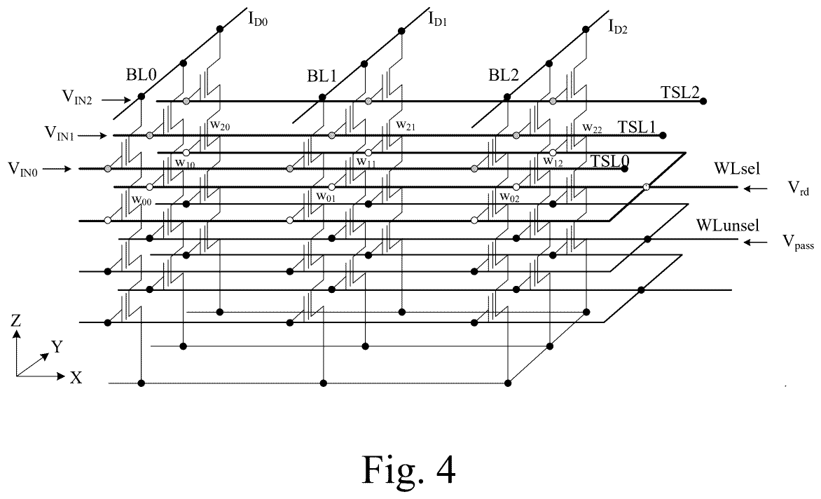

In order to achieve the above operation functions, the memory cell array of the three-dimensional NAND memory device may be configured to store a weight matrix. Specifically, before starting the operation, weights in the weight matrix may be written into the memory cell array according to a certain mapping rule, and each memory cell in the memory cell array may be configured to store one weight. When performing the operation, a semiconductor device may receive input data from a controller, which may include an input vector or matrix composed of a plurality of elements. Each element in the input data may be converted into an input voltage through a digital-to-analog conversion circuit and input into a memory cell array through an upper select line. The following will provide an example explanation of using a three-dimensional NAND memory device for operations, in connection with FIG. 4.

FIG. 4 is a schematic diagram of using a three-dimensional NAND memory device for computing-in-memory according to an example. Referring to FIG. 4, before starting the operation, a plurality of weights (e.g. weights w₀₀ to w₂₂) in the weight matrix are written into a plurality of memory cells coupled to the selected word line WLsel. When performing the operation, an input voltage obtained by converting the input data is applied to the corresponding upper select lines (for example, input voltages V_{IN0}, V_{IN1}, V_{IN2} are applied to the upper selection lines TSL0, TSL1, and TSL2, respectively), and a read voltage V_{rd} is applied to the selected word line WLsel and a pass voltage Vₚₐₛₛ is applied to the unselected word line WLunsel. The operation result may be obtained by sensing a current on the bit line and converting the current. Taking bit line BL0 as an example, the current I_{D0} on bit line BL0 corresponds to the result of accumulating a product of an element corresponding to input voltage V_{IN0} and weight woo, a product of an element corresponding to input voltage V_{IN1} and weight w₁₀, and a product of an element corresponding to input voltage V_{IN2} and weight w₂₀. The current IDI on bit line BL1 and the current I_{D2} on bit line BL2 may be understood by referring to the current I_{D0} on bit line BL0.

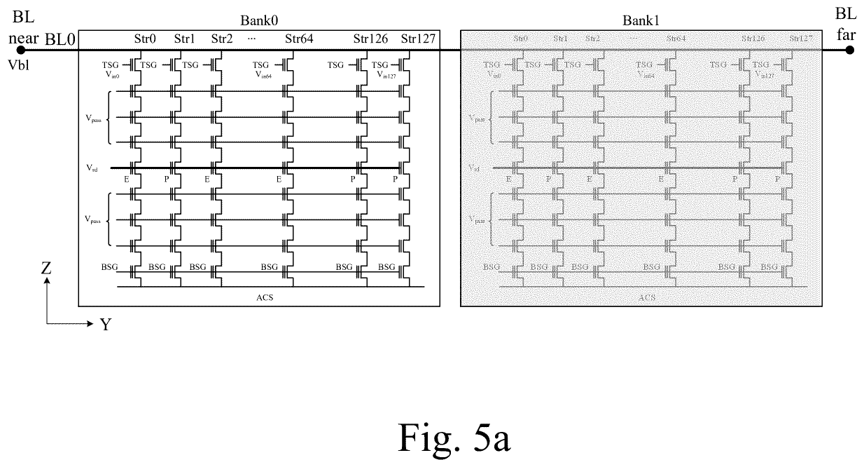

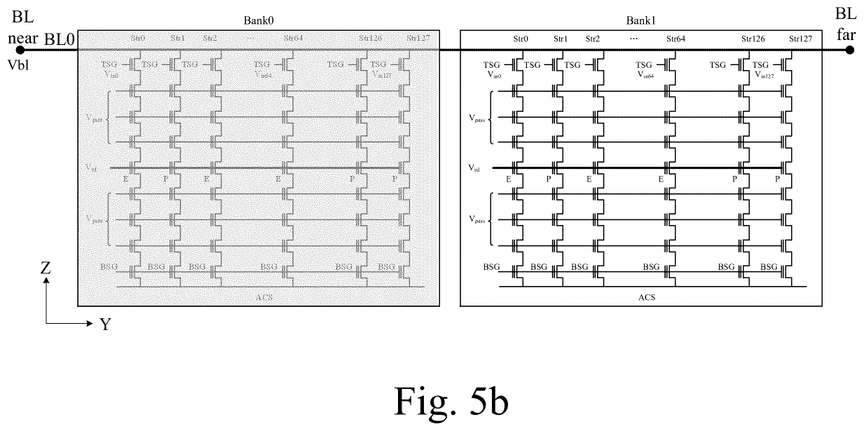

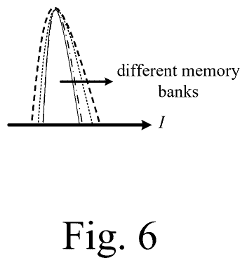

In the NAND computing-in-memory chip shown in FIG. 4, a weight is stored in a memory cell, and an input voltage corresponding to input data is input through an upper select line, and a bit line outputs the corresponding current. Due to the significant difference between the current corresponding to the erase state and the current corresponding to the program state of the memory cell, the final addition operation is performed by using the current on the bit line based on the Kirchhoff's law, wherein the addition operation of the current on the bit line is performed by parallel operations of a plurality of memory strings coupled to the same bit line. For case of understanding, a plurality of memory strings operating in parallel at the same time are referred to as a memory bank. Considering the cost of process and circuit design, a plurality of memory banks are coupled to the same bit line, and the plurality of memory banks coupled to the same bit line are operated in a time-division manner. Therefore, it is necessary to consider that different memory banks coupled to the same bit line are subject to different bit line voltage drops (BL IR Drop) during operation, which leads to the difference in current spreading of different memory banks and affects the accuracy of computing-in-memory, as will be further explained in connection with FIGS. 5 and 6.

FIGS. 5a and 5b are schematic diagrams of a time-division operation of a plurality of memory banks coupled to a bit line according to an example, and FIG. 6 is a schematic diagram of a current distribution on a bit line according to an example. For ease of understanding, the following will take BL0 being coupled to two memory banks (e.g., a first memory bank Bank0 and a second memory bank Bank1), each memory bank including 128 memory strings (e.g., memory strings Str0 to Str127) as an example for illustration. Other bit lines and memory banks coupled to them may be understood with reference to FIGS. 3 and 5.

Referring to FIG. 5a, at a first time instance, a bit line voltage Vbl is applied to the bit line BL0, and input voltages Vᵢₙ₀ to Vᵢₙ₁₂₇ are applied to 128 upper select lines coupled to the first memory bank Bank0, respectively, and a current on the bit line BL0 is sensed, so as to perform a corresponding parallel operation on the first memory bank Bank0. Here, at the first time instance, no voltage is applied to the 128 upper select lines coupled to the second memory bank Bank1, as shown in FIG. 5a.

Referring to FIG. 5b, at a second time instance, a bit line voltage Vbl is applied to bit line BL0, and input voltages Vᵢₙ₀ to Vᵢₙ₁₂₇ are applied to 128 upper select lines coupled to the second memory bank Bank1, respectively and a current on bit line BL0 is sensed, so as to perform a corresponding parallel operation on the second memory bank Bank1. Here, at the second time instance, no voltage is applied to the 128 upper select lines coupled to the first memory bank Bank0, as shown in FIG. 5b.

In some example, the second time instance is different from the first time instance. For example, the second time instance may be later or earlier than the first time instance, thereby enabling the time-division operation of the first memory bank Bank0 and the second memory bank Bank1. During the process of performing a corresponding parallel operation on each memory bank, a read voltage V_{rd} may also be applied to a selected word line, and a pass voltage Vₚₐₛₛ may be applied to an unselected word line. The input voltages applied to the upper select lines corresponding to different memory banks may be the same or different, and the present disclosure has no special limitation on this. In practical applications, a plurality of memory banks may be obtained by dividing a plurality of memory strings coupled to the same bit line based on the number of elements in the input data (the number of input voltages). For example, if 256 memory strings are coupled to the same bit line and the number of elements in the input data is 128 at each time instance, a plurality of memory strings coupled to the same bit line may be divided into 2 memory banks. As another example, if 256 memory strings are coupled to the same bit line and the number of elements in the input data is 64 at each time instance, a plurality of memory strings coupled to the same bit line may be divided into 4 memory banks.

In the schemes shown in FIGS. 5a and 5b, the first bank Bank0 and the second bank Bank1 coupled to BL0 are affected differently by a bit line voltage drop. Specifically, from the near end of the bit line to the far end of the bit line, the bit line voltage drops of the first bank Bank0 and the second bank Bank1 increase gradually. That is, the bit line voltage drop of the first bank Bank0 is smaller than the bit line voltage drop of the second bank Bank1, which causes effective voltages of the bit lines corresponding to the first bank Bank0 and the second bank Bank1 to be different, resulting in differences in the current spreading of different banks, as shown in FIG. 6, and reducing the accuracy of computing-in-memory. Here, BL near and BL far in FIGS. 5a and 5b represent the near end and far end of the bit line, respectively.

Based on one or more of the technical problems mentioned above, an example of the present disclosure provides a semiconductor device. The semiconductor device includes a plurality of memory banks and a peripheral circuit coupled to the plurality of memory banks through a bit line. The peripheral circuit is configured to: provide a first voltage to the bit line and sense a current on the bit line during a first read stage of a first memory bank of the plurality of memory banks; and provide a second voltage to the bit line and sense a current on the bit line during a second read stage of a second memory bank of the plurality of memory banks, wherein the first memory bank and the second memory bank are arranged along a direction from a first end of the bit line pointing to a second end of the bit line, the first end is a node where the bit line is coupled to a page buffer or a bit line driver, the second read stage is different from the first read stage, and the second voltage is greater than the first voltage, and/or a sense duration of the second read stage is greater than a sense duration of the first read stage. In such a way, the difference in bit line voltage drop among a plurality of memory banks coupled to the same bit line may be compensated, and the accuracy of computing-in-memory is improved.

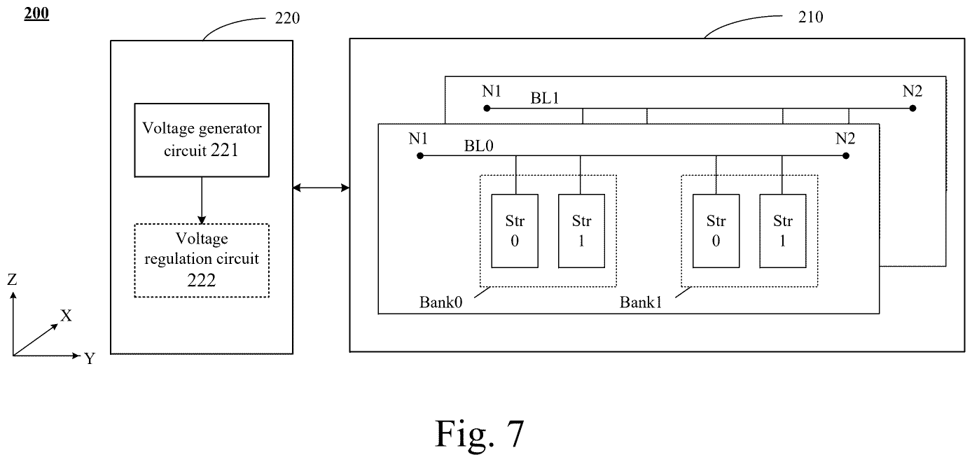

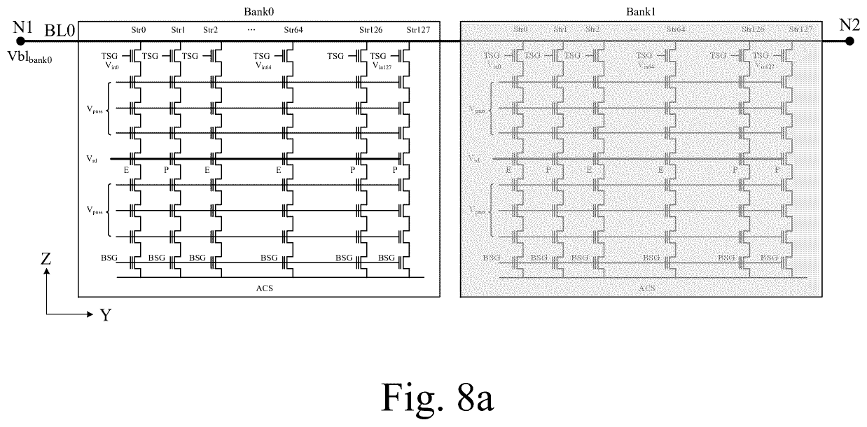

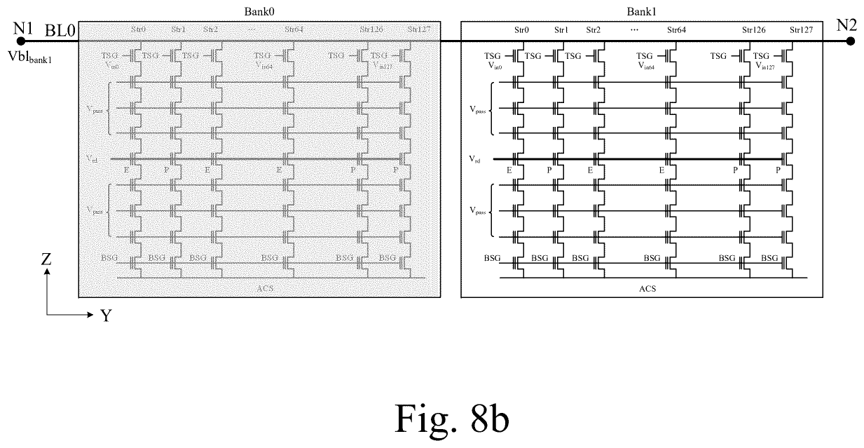

FIG. 7 is a schematic diagram of a semiconductor device according to an example of the present disclosure. FIG. 8a is a schematic diagram of a first read stage according to a first example of the present disclosure. FIG. 8b is a schematic diagram of a second read stage according to a first example of the present disclosure. A semiconductor device includes but is not limited to a three-dimensional NAND memory device, and examples of the present disclosure will take a three-dimensional NAND memory device as an example for illustration.

Referring to FIG. 7, the semiconductor device 200 includes a memory cell array 210 and a peripheral circuit 220. The memory cell array 210 includes a plurality of memory banks, and the peripheral circuit 220 may be coupled to a plurality of memory banks through a bit line BL0, a word line, and other drive/select lines. For case of understanding, two bit lines BL0 and BL1 are shown in FIG. 7. Regarding a word line and other drive/select lines, please refer to the relevant description above. Each bit line BL0 is coupled to a plurality of memory banks arranged along the Y direction. For example, the bit line BL0 is coupled to the first memory bank Bank0 and the second memory bank Bank1. Each memory bank includes a plurality of memory strings. For example, the first memory bank Bank0 includes memory strings Str0 and Str1, and the second memory bank Bank1 includes memory strings Str0 and Str1.

In some examples, the number of bit lines, the number of memory banks coupled to each bit line, and the number of memory strings in each memory bank in the semiconductor device 200 are not limited to those shown in FIG. 7 and other numbers are not excluded. In addition, the number of memory strings in different memory banks may be the same or different, and the present disclosure has no special restrictions on this. The first direction and the second direction used in this example and the following are respectively represented as the Y direction and X direction in the accompanying drawings. The Y direction and the X direction intersect and are both perpendicular to the Z direction in the accompanying drawings, wherein the Y direction is the direction in which each bit line extends, the X direction is the direction in which a plurality of bit lines are arranged, and the Z direction is the direction in which each memory string extends.

The peripheral circuit 220 is configured to: provide a first voltage Vbl_{bank0} to the bit line BL0, and sense a current on the bit line BL0 during the first read stage of the first bank Bank0 of a plurality of banks; and provide a second voltage Vbl_{bank1} to the bit line BL0 and sense a current on the bit line BL0 during a second read stage of the second bank Bank1 of the plurality of banks, wherein the first memory bank Bank0 and the second memory bank Bank1 are arranged along a direction from a first end N1 of the bit line BL0 pointing to a second end N2 of the bit line BL0. The first end N1 is a node where the bit line BL0 is coupled to a page buffer or a bit line driver. The second read stage is different from the first read stage. The second voltage Vbl_{bank1} is greater than the first voltage Vbl_{bank0}, and/or a sense duration of the second read stage is greater than a sense duration of the first read stage.

The first end N1 used in the present disclosure is a node where the bit line is coupled to a page buffer or a bit line driver, that is, the first end N1 is a near end of the bit line, and the second end N2 is a far end of the bit line. In such a way, the difference in bit line voltage drop among a plurality of memory banks coupled to the same bit line may be compensated, improving the accuracy of computing-in-memory. Here, the page buffer or bit line driver may be coupled to one of two endpoints of the bit line that is relatively far away from the memory cell array 210, or to any intermediate node between two endpoints of the bit line. In order to provide a more detailed description of the present disclosure, the following will take BL0 being coupled to two memory banks (e.g., the first memory bank Bank0 and the second memory bank Bank1), each memory bank including 128 memory strings (e.g., memory strings Str0 to Str127) as an example for illustration of the first and second read stages of the first example in connection with FIGS. 8a and 8b.

Referring to FIG. 8a, during the first read stage, the peripheral circuit 220 may provide a first voltage Vbl_{bank0} to the bit line BL0, and apply input voltages Vᵢₙ₀ to Vᵢₙ₁₂₇ to 128 upper select lines coupled to the first memory bank Bank0, apply a read voltage V_{rd} to the selected word line, and apply a pass voltage Vₚₐₛₛ to the unselected word line, and then sense a current on the bit line BL0. Here, during the first read stage, no voltage is applied to the 128 upper select lines coupled to the second memory bank Bank1, that is, the second memory bank Bank1 is not selected, as shown in FIG. 8a.

Referring to FIG. 8b, during the second read stage, the peripheral circuit 220 may provide a second voltage Vbl_{bank1} to the bit line BL0, and apply input voltages Vᵢₙ₀ to Vᵢₙ₁₂₇ to the 128 upper select lines coupled to the second memory bank Bank1, apply a read voltage V_{rd} to the selected word line, and apply a pass voltage Vₚₐₛₛ to the unselected word line, and then sense a current on the bit line BL0. Here, during the second read stage, no voltage is applied to the 128 upper select lines coupled to the first memory bank Bank0, that is, the first memory bank Bank0 is not selected, as shown in FIG. 8b. The second read stage is different from the first read stage. For example, the second read stage may be later or earlier than the first read stage, thereby enabling a time-division operation of the first memory bank Bank0 and the second memory bank Bank1.

In the examples shown in FIGS. 8a and 8b, corresponding input voltages are applied to a plurality of upper select lines coupled to different memory banks. However, in another example, the peripheral circuit 220 is further configured to: apply corresponding input voltages to a plurality of first select lines coupled to the first memory bank Bank0 during the first read stage; and apply corresponding input voltages to a plurality of second select lines coupled to the second memory bank Bank1 during the second read stage. Here, the first select line includes a plurality of upper select lines coupled to the first memory bank Bank0 or a plurality of lower select lines coupled to the first memory bank Bank0, and the second select line includes a plurality of upper select lines coupled to the second memory bank Bank1 or a plurality of lower select lines coupled to the second memory bank Bank1. In other words, input voltages may be input through upper or lower select lines coupled to a corresponding memory bank.

In one example, the second voltage Vbl_{bank1} is greater than the first voltage Vbl_{bank0}, and the sense duration of the second read stage may be equal to the sense duration of the first read stage. In this example, during different read stages of a plurality of memory banks coupled to the same bit line, by providing different bit line voltages, the difference in bit line voltage drop among a plurality of memory banks coupled to the same bit line may be compensated, thereby improving the accuracy of computing-in-memory.

In another example, a sense duration of the second read stage is greater than a sense duration of the first read stage, and the second voltage Vbl_{bank1} may be equal to the first voltage Vbl_{bank0}. In this example, during different read stages of a plurality of memory banks coupled to the same bit line, by setting different sense durations, the difference in bit line voltage drop among a plurality of memory banks coupled to the same bit line may be compensated, thereby improving the accuracy of computing-in-memory.

Of course, the above two examples may be combined, that is, the second voltage Vbl_{bank1} is greater than the first voltage Vbl_{bank0}, and a sense duration of the second read stage is greater than a sense duration of the first read stage.

In some examples, a plurality of memory banks coupled to a bit line form a plurality of memory bank groups, wherein the first memory bank and the second memory bank are in different memory bank groups, respectively. Here, each memory bank group may include at least one memory bank, and the number of memory banks in any two memory bank groups may be the same or different.

In the example of the present disclosure, a plurality of memory banks coupled to the same bit line may be grouped to obtain a plurality of memory bank groups arranged along the Y direction, wherein in the direction from the first end N1 pointing to the second end N2, the bit line voltages of a plurality of memory bank groups during the corresponding read stages increase gradually, that is, the smaller the bit line voltage of a memory bank group closer to the first end N1 during the read stage is, the larger the bit line voltage of a memory bank group closer to the second end N2 during the read stage is. For example, in a case where the first bank Bank0 and the second bank Bank1 belong to different bank groups, the voltage provided to the bit line BL0 during the second read stage may be greater than the voltage provided to the bit line BL0 during the first read stage, that is, the second voltage Vbl_{bank1} is greater than the first voltage Vbl_{bank0}.

In some example, in the case where a memory bank group includes a plurality of memory banks, the bit line voltages of a plurality of memory banks in the same memory bank group during the corresponding read stage may be the same or different, depending on the magnitude of the difference in bit line voltage drop of the plurality of memory banks in the same memory bank group. For example, if the bit line voltage drops of a plurality of banks in the same memory bank group are the same or the difference is small, the bit line voltages of a plurality of memory banks in the same memory bank group during the corresponding read stage may be the same, thereby simplifying an operation. For example, if there is a significant difference among bit line voltage drops of a plurality of memory banks in the same memory bank group, the bit line voltages of a plurality of memory banks in the same memory bank group during the corresponding read stage may be different, thereby compensating for the difference in bit line voltage drops among a plurality of memory banks in the same memory bank group.

In some other examples, the first memory bank and the second memory bank are in the same memory bank group. In an example of the present disclosure, in the case where the memory bank group includes a plurality of memory banks, along the direction from the first end N1 of the bit line pointing to the second end N2 of the bit line, the bit line voltages of a plurality of memory banks in the same memory bank group during the corresponding read stage may be the same or increased gradually. For example, in the case where the first bank Bank0 and the second bank Bank1 belong to the same bank group, the voltage provided to the bit line BL0 during the second read stage may be greater than or equal to the voltage provided to the bit line BL0 during the first read stage, that is, the second voltage Vbl_{bank1} is greater than or equal to the first voltage Vbl_{bank0}.

In some examples, as shown in FIG. 7, the peripheral circuit 220 includes a voltage generation circuit 221 and a voltage regulation circuit 222. The voltage generation circuit 221 is configured to generate an initial voltage, wherein the initial voltage is greater than or equal to the second voltage Vbl_{bank1}. The voltage regulation circuit 222 is coupled to the voltage generation circuit 221 and a bit line, respectively. The voltage regulation circuit 222 is configured to regulate the initial voltage to the first voltage Vbl_{bank0} during a first read stage; and regulate the initial voltage to the second voltage Vbl_{bank1} during a second read stage.

In the example of the present disclosure, in the case where a time-division read is performed on a plurality of memory banks coupled to the same bit line, the voltage generation circuit 221 may generate a fixed initial voltage. During the first read stage, the voltage regulation circuit 222 may regulate the initial voltage to the first voltage Vbl_{bank0} and provide Vbl_{bank0} to the bit line BL0. During the second read stage, the voltage regulation circuit 222 may regulate the initial voltage to the second voltage Vbl_{bank1} and provide Vbl_{bank1} to the bit line BL0. In such a way, the voltage regulation circuit 222 may regulate the fixed initial voltage to different bit line voltages during the corresponding reading stage of a plurality of memory banks coupled to the same bit line, to compensate for the difference in bit line voltage drops among a plurality of memory banks coupled to the same bit line.

In some examples, the peripheral circuit 220 includes a control logic coupled to the voltage generation circuit 221 and the voltage regulation circuit 222, respectively. The control logic is configured to generate a control signal, a first regulation signal, and a second regulation signal, wherein the control signal is configured to indicate to generate an initial voltage, the first regulation signal is configured to indicate to regulate the initial voltage to the first voltage Vbl_{bank0}, and the second regulation signal is configured to indicate to regulate the initial voltage to the second voltage Vbl_{bank1}. In the example of the present disclosure, the voltage generation circuit 221 and the voltage regulation circuit 222 may perform corresponding operations under the control of the control logic. For example, the voltage generation circuit 221 may generate an initial voltage based on a control signal, and the voltage regulation circuit 222 may regulate the initial voltage to the first voltage Vbl_{bank0} based on the first regulation signal and regulate the initial voltage to the second voltage Vbl_{bank1} based on the second regulation signal. It may be understood that the control logic may generate any one of the control signal, the first regulation signal, and the second regulation signal at different time instances to control the voltage generation circuit 221 and the voltage regulation circuit 222 to perform corresponding operations. Regarding the control logic, please refer to the relevant description in FIG. 1, which will not be repeated here.

In some examples, the voltage regulation circuit 222 includes a variable resistor. It may be understood that in the example of the present disclosure, the resistance value of the variable resistor may be changed to regulate the voltage applied to the bit line, thereby providing different voltages to the bit line, and simplifying operations. Of course, the voltage regulation circuit 222 may also include other electronic components that may regulate a bit line voltage.

In some examples, the peripheral circuit 220 includes a voltage generation circuit 221 coupled to a bit line. The voltage generation circuit 221 is configured to generate a first voltage Vbl_{bank0} during the first read stage and generate a second voltage Vbl_{bank1} during the second read stage.

In the example of the present disclosure, in the case where a time-division read is performed on a plurality of memory banks coupled to the same bit line, the voltage generation circuit 221 may generate different voltages at different read stages and provide them to the bit line. For example, during the first read stage, the voltage generation circuit 221 may generate the first voltage Vbl_{bank0} and provide it to the bit line BL0. During the second read stage, the voltage generation circuit 221 may generate the second voltage Vbl_{bank1} and provide it to the bit line BL0. In such a way, the voltage generation circuit 221 may generate different bit line voltages during the corresponding reading stage of a plurality of memory banks coupled to the same bit line, to compensate for the difference in bit line voltage drops among a plurality of memory banks coupled to the same bit line. It may be understood that the voltage regulation circuit 222 may be omitted in the example of the present disclosure, as shown by the dashed box in FIG. 7.

In some examples, the control logic is coupled to the voltage generation circuit 221. The control logic is configured to generate a first control signal and a second control signal, wherein the first control signal is configured to indicate to generate the first voltage Vbl_{bank0}, and the second control signal is configured to indicate to generate the second voltage Vbl_{bank1}. In the example of the present disclosure, the voltage generation circuit 221 may perform corresponding operations under the control of the control logic. For example, the voltage generation circuit 221 may generate a first voltage Vbl_{bank0} based on the first control signal and generate a second voltage Vbl_{bank1} based on the second control signal. It may be understood that the control logic may generate different control signals at different time instances to control the voltage generation circuit 221 to perform corresponding operations. Regarding the control logic, please refer to the relevant description in FIG. 1, which will not be repeated here.

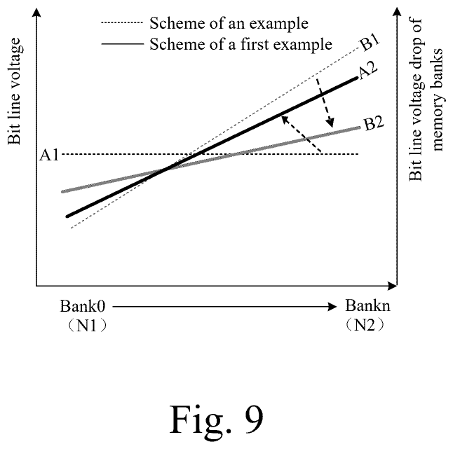

FIG. 9 is a first schematic diagram of a bit line voltage drop according to different examples shown in the present disclosure. The dashed line in FIG. 9 represents an example, wherein the dashed line A1 represents that the bit line voltages of n memory banks coupled to the same bit line during the read stage are the same, and the dashed line B1 represents the variation rule of bit line voltage drops of n memory banks coupled to the same bit line. The solid line in FIG. 9 represents a first example, wherein the solid line A2 represents that the bit line voltages of n memory banks coupled to the same bit line during the read stage increases gradually, and the solid line B2 represents the variation rule of bit line voltage drop of n memory banks coupled to the same bit line, wherein n is an integer greater than 1. From FIG. 9, it may be seen that by setting the bit line voltages during the read stage of n memory banks coupled to the same bit line to increase gradually, the difference in bit line voltage drop of n memory banks coupled to the same bit line may be compensated, as shown by the dashed line B1 to the solid line B2 in FIG. 9. Here, the detailed content of examples may refer to the examples related to FIGS. 5a and 5b, and the detailed content of the first example may refer to the examples related to FIGS. 8a and 8b, which will not be repeated for simplicity.

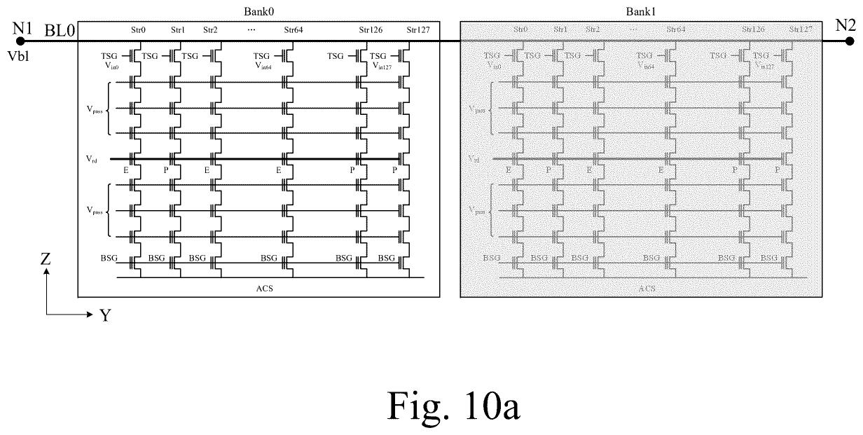

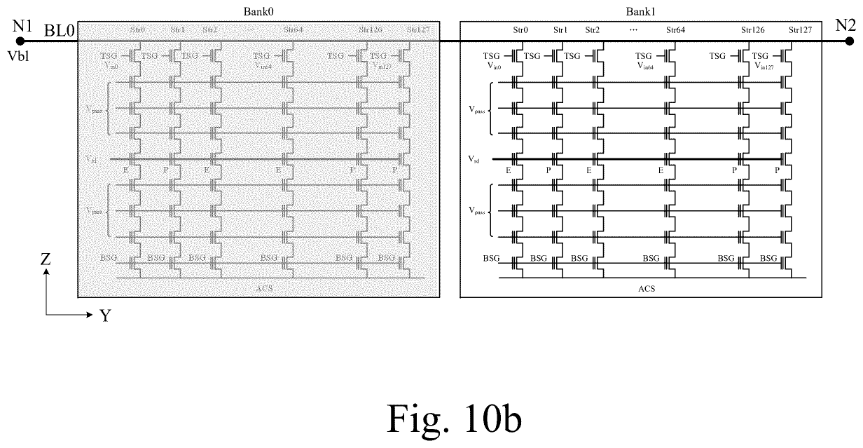

FIG. 10a is a schematic diagram of a first read stage according to a second example of the present disclosure. FIG. 10b is a schematic diagram of a second read stage according to a second example of the present disclosure. Referring to FIGS. 10a and 10b, both the first voltage and the second voltage are voltage Vbl, the second voltage is equal to the first voltage. In the case where the second voltage is equal to the first voltage, a sense duration of the second read stage may be greater than a sense duration of the first read stage, a sense duration of bit line BL0 in FIG. 10a is greater than a sense duration of bit line BL0 in FIG. 10b.

In some examples, in the case where a sense duration of the second read stage is greater than a sense duration of the first read stage, a first reference current corresponding to the first read stage is greater than a second reference current corresponding to the second read stage.

During a read stage, a read result may be generated by comparing a sensed current on a bit line with a reference current. For example, if the sensed current on the bit line is greater than the reference current, a logic value of “1” may be generated. If the sensed current on the bit line is less than or equal to the reference current, a logic value of “0” may be generated. The reference current may be calculated using equation 1. In equation 1, I_{ref} represents a reference current; Cₛₒ represents a coupling capacitance of a sensing node; ΔV_{IR} represents a voltage drop; and t_{sodev} represents a sense duration.

$${I}_{ref} = Cso \times \frac{Δ {V}_{IR}}{{t}_{sodev}} \qquad Equation 1$$

According to equation 1, the reference current is inversely proportional to the sense duration. Therefore, by setting a sense duration of the second read stage to be greater than a sense duration of the first read stage, the first reference current corresponding to the first read stage may be greater than the second reference current corresponding to the second read stage, that is, different reference currents may be designed for memory banks with different bit line voltage drops. Specifically, the smaller the bit line voltage drop corresponding to the memory bank is, the larger the corresponding reference current is, and the greater the bit line voltage drop corresponding to the memory bank is, the smaller the corresponding reference current is. In such a way, the difference in bit line voltage drops among a plurality of memory banks coupled to the same bit line may be compensated, therefore avoiding erroneous readings caused by bit line voltage drops.

In some examples, the peripheral circuit 220 is further configured to: generate a first read result based on the sensed current on the bit line during the first read stage and the first reference current; and generate a second read result based on the sensed current on the bit line during the second read stage and the second reference current. For example, the sensed current on the bit line during the first read stage may be compared with the first reference current to generate the first read result, and the sensed current on the bit line during the second read stage may be compared with the second reference current to generate the second read result. Here, the sensed current on the bit line during the first read stage and the sensed current on the bit line during the second read stage may be the same or different. In practical applications, the sensed current on the bit line and the reference current may be converted into two voltages separately (for example, using a voltage divider resistor). The sensing amplifier in FIG. 1 amplifies the converted two voltage swings to recognizable logic levels, thereby obtaining the corresponding read result.

In some examples, both the first and second read results are analog operation results. The analog operation results are transmitted to an analog-to-digital conversion circuit through the page buffer 122 and column decoder in FIG. 1. The analog-to-digital conversion circuit converts the analog operation results into digital operation results and transmits the final digital operation results to the control logic 121 in FIG. 1, thereby realizing the multiplication operation or multiply-accumulate operation of input data and a weight matrix.

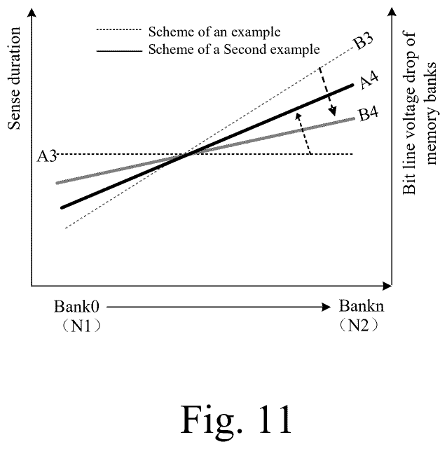

FIG. 11 is a schematic diagram of a bit line voltage drop according to different examples shown in the present disclosure. The dashed lines in FIG. 11 represent an example, wherein dashed line A3 represents that the sense duration of the read stages of n memory banks coupled to the same bit line are the same, and dashed line B3 represents the variation rule of bit line voltage drops of n memory banks coupled to the same bit line. The solid line in FIG. 11 represents the second example, wherein solid line A4 represents that the sense durations of the read stages of n memory banks coupled to the same bit line increase gradually, and solid line B4 represents the variation rule of bit line voltage drops of n memory banks coupled to the same bit line, wherein n is an integer greater than 1. From FIG. 11, it may be seen that by setting the sense durations of the read stages of n memory banks coupled to the same bit line to increase gradually, the difference in bit line voltage drops of n memory banks coupled to the same bit line may be compensated, as shown by the dashed line B3 to the solid line B4 in FIG. 11. Here, the detailed content of the examples may refer to the examples related to FIGS. 5a and 5b, and the detailed content of the first example may refer to the examples related to FIGS. 8a and 8b, which will not be repeated for simplicity. In the examples shown in FIGS. 5a and 5b, the sense durations of the first bank Bank0 and the second bank Bank1 are the same.

Based on the above semiconductor devices, an example of the present disclosure provides a method of operating a semiconductor device. The method may be used for the semiconductor device in any of the above examples. For example, the method may be used to perform an operation on a semiconductor device, wherein the memory cell array of the semiconductor device is configured to store a weight matrix.

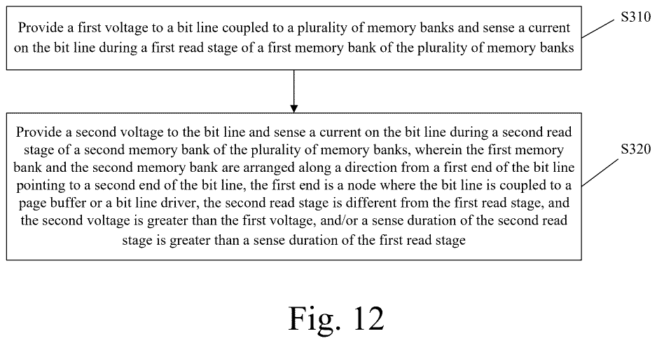

FIG. 12 is a flowchart of a method of operating a semiconductor device according to an example of the present disclosure. It should be noted that the operations shown in FIG. 12 are not exclusive and other operations may be performed before, after, or between any of the shown operations. The operations shown in FIG. 12 may be adjusted in order according to actual needs. Referring to FIG. 12, the method includes the following operations:

Operation S310: Provide a first voltage to the bit line coupled to a plurality of memory banks and sense a current on the bit line during a first read stage of a first memory bank of the plurality of memory banks.

Operation S320: Provide a second voltage to the bit line and sense a current on the bit line during a second read stage of a second memory bank of the plurality of memory banks, wherein the first memory bank and the second memory bank are arranged along a direction from a first end of the bit line pointing to a second end of the bit line, the first end is a node where the bit line is coupled to a page buffer or a bit line driver, the second read stage is different from the first read stage, and the second voltage is greater than the first voltage, and/or a sense duration of the second read stage is greater than a sense duration of the first read stage.

For example, a plurality of weights of the weight matrix may be written into a plurality of memory banks, respectively, before performing an operation using a semiconductor device. When performing a first operation using the semiconductor device, a first voltage is provided to the bit line coupled to the first memory bank, and a read voltage V_{rd} and a pass voltage Vₚₐₛₛ are applied to a selected and unselected word line of a plurality of word lines, respectively. The input voltage obtained by converting the input data is applied to a plurality of upper select lines coupled to the first memory bank, and then the current on the bit line is sensed, as shown in FIG. 8a. When performing a second operation using the semiconductor device, a second voltage is provided to the bit line coupled to the second memory bank, and a read voltage V_{rd} and a pass voltage Vₚₐₛₛ are applied to a selected and unselected word line of a plurality of word lines, respectively. The input voltage obtained by converting the input data is applied to a plurality of upper select lines coupled to the second memory bank, and then the current on the bit lines is sensed, as shown in FIG. 8b.

It should be noted that a read result may be obtained by sensing the current on the bit line. The read result may be converted into a digital operation result through an analog-to-digital conversion circuit. Therefore, the first operation includes at least the first read stage mentioned above, and the second operation includes at least the second read stage.

In some examples, the method further includes: generating an initial voltage; wherein the initial voltage is greater than or equal to the second voltage; regulating the initial voltage to the first voltage during the first read stage; and regulating the initial voltage to the second voltage during the second read stage. The process of generating the initial voltage and regulating the initial voltage to the first voltage and the second voltage respectively during the first read stage and the second read stage may refer to the relevant descriptions of the above examples, which will not be repeated here.

In some examples, the method further includes: generating a first voltage during the first read stage; and generating a second voltage during the second read stage. The process of generating the first voltage and the second voltage respectively during the first read stage and the second read stage may refer to the relevant descriptions of the above examples, which will not be repeated here.

In some examples, in the case where a sense duration of the second read stage is greater than a sense duration of the first read stage, the first reference current corresponding to the first read stage is greater than the second reference current corresponding to the second read stage.

In some examples, the method further includes: generating a first read result based on the sensed current on the bit line during the first read stage and the first reference current; and generating a second read result based on the sensed current on the bit line during the second read stage and the second reference current.

In some examples, a plurality of memory banks coupled to the bit line form a plurality of memory bank groups, wherein the first memory bank and the second memory bank are in different memory bank groups.

In some examples, a plurality of memory banks coupled to the bit line form a plurality of memory bank groups, wherein the first memory bank and the second memory bank are in the same memory bank group.

In some examples, the method further includes: during the first read stage, applying corresponding input voltages to a plurality of first select lines coupled to the first memory bank; and during the second read stage, applying corresponding input voltages to a plurality of second select lines coupled to the second memory bank.

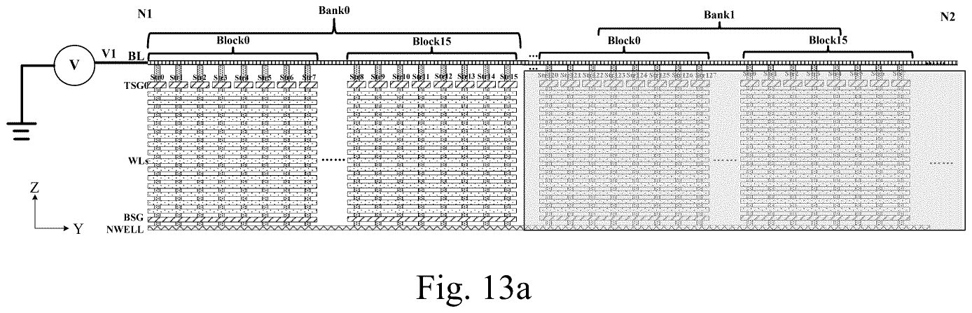

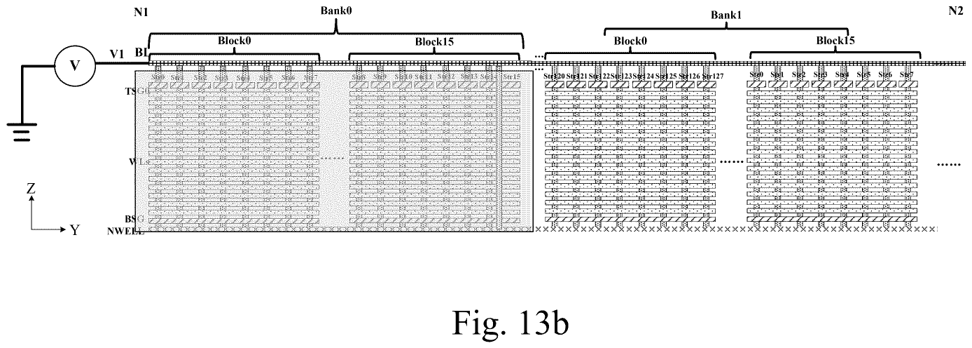

FIGS. 13a and 13b are schematic diagrams of providing the same voltage to a bit line at different time instances according to an example. Referring to FIG. 13a, the voltage V1 is applied to the bit line BL at both first and second time instances. The voltage applied to the word line and the upper select line at the first and second time instances may refer to the relevant descriptions of FIGS. 5a and 5b. Since the bit line voltage drop of the first bank Bank0 is smaller than the bit line voltage drop of the second bank Bank1, the effective voltages of the bit lines corresponding to the first bank Bank0 and the second bank Bank1 are different, resulting in differences in the current spreading of different banks. Here, each memory bank may include a plurality of memory blocks, and each memory block may include a plurality of memory strings. For example, FIGS. 13a and 13b show that each memory bank includes 16 memory blocks, represented as Block0 to Block15, respectively. Each memory block includes 8 memory strings, represented as Str0 to Str7.

Based on this, an example of the present disclosure provides a semiconductor device. The semiconductor device includes a plurality of memory banks and a voltage regulation circuit coupled to the plurality of memory banks through a bit line. The voltage regulation circuit is configured to: regulate the initial voltage to the first voltage and provide the first voltage to the bit line during the first read stage of the first memory bank of a plurality of memory banks; and regulate the initial voltage to the second voltage and provide the second voltage to the bit line during the second read stage of the second memory bank of a plurality of memory banks, wherein the first memory bank and the second memory bank are arranged along a direction from the first end of the bit line pointing to the second end of the bit line, the first end is a node where the bit line is coupled to a page buffer or bit line driver, the second read stage is different from the first read stage, the initial voltage is greater than or equal to the second voltage, and the second voltage is greater than the first voltage. In such a way, the difference in bit line voltage drops among a plurality of memory banks coupled to the same bit line may be compensated, thereby improving the accuracy of computing-in-memory.

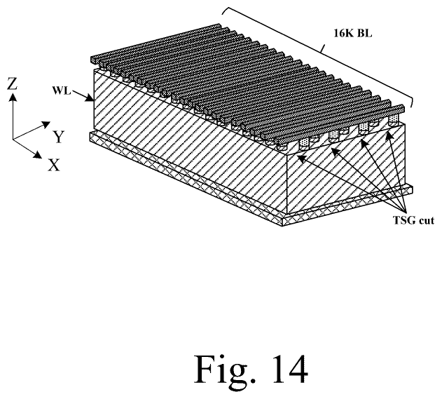

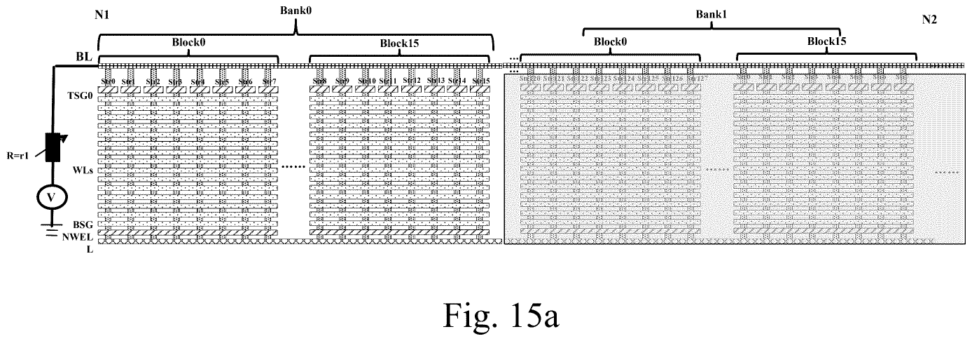

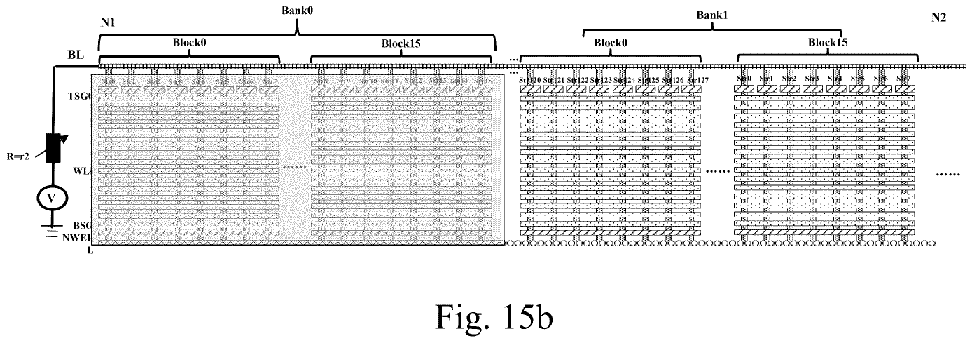

FIG. 14 is a three-dimensional schematic diagram of a semiconductor device according to an example of the present disclosure. FIG. 15a is a schematic diagram of a first read stage according to a third example of the present disclosure, and FIG. 15b is a schematic diagram of a second read stage according to a third example of the present disclosure. A semiconductor device may include but is not limited to a three-dimensional NAND memory device, and the example of the present disclosure will take a three-dimensional NAND memory device as an example for illustration.

Referring to FIG. 14, the semiconductor device includes a memory cell array and a peripheral circuit. The peripheral circuit may be coupled to the memory cell array through a plurality of word lines WL and a plurality of bit lines BL. Each word line WL is coupled to a plurality of memory cells at the same level, each bit line BL is coupled to a plurality of memory strings arranged along the Y direction, and a plurality of memory cells arranged along the Z direction and connected in series form a memory string. For case of illustration, a plurality of memory cells and memory strings are not shown in FIG. 14.

The peripheral circuit may include a voltage regulation circuit and a voltage generation circuit coupled to the voltage regulation circuit. The voltage generation circuit is configured to generate an initial voltage and provide it to the voltage regulation circuit.

Regarding the voltage generation circuit, please refer to the relevant description in FIG. 7, which will not be repeated here.

In some examples, as shown in FIGS. 15a and 15b, the voltage regulation circuit includes a variable resistor R. Of course, the voltage regulation circuit also includes other electronic components that may regulate a bit line voltage. For case of understanding, the following will take the voltage regulation circuit including a variable resistor R as an example for illustration.

Referring to FIG. 15a, during the first read stage, the resistance value of the variable resistor R is r1. Due to the voltage division of the variable resistor R with a resistance of r1, the initial voltage may be regulated to the first voltage. Referring to FIG. 15b, during the second read stage, the resistance value of the variable resistor R is r2. Due to the voltage division of the variable resistor R with a resistance value of r2, the initial voltage may be regulated to the second voltage. here, r1>r2, the voltage division of the variable resistor R during the first read stage is greater than that of the variable resistor R during the second read stage, so that the first voltage is lower than the second voltage. It should be noted that during the first read stage, the second memory bank Bank1 is not selected, as shown in FIG. 15a, and during the second read stage, the first memory bank Bank0 is not selected, as shown in FIG. 15b.

In some examples, a plurality of memory banks coupled to the bit line form a plurality of memory bank groups, wherein the first memory bank and the second memory bank are in different memory bank groups. For example, the first memory bank Bank0 and the second memory bank Bank1 shown in FIGS. 15a and 15b may be in different memory bank groups. The content about the first memory bank Bank0 and the second memory bank Bank1 being in different memory bank groups may refer to the relevant descriptions of the above examples, which will not be repeated here.

In some other examples, the first memory bank and the second memory bank are in the same memory bank group. For example, the first memory bank Bank0 and the second memory bank Bank1 shown in FIGS. 15a and 15b may be in the same memory bank group. The content about the first memory bank Bank0 and the second memory bank Bank1 being in the same memory bank group may refer to the relevant descriptions of the above examples, which will not be repeated here.

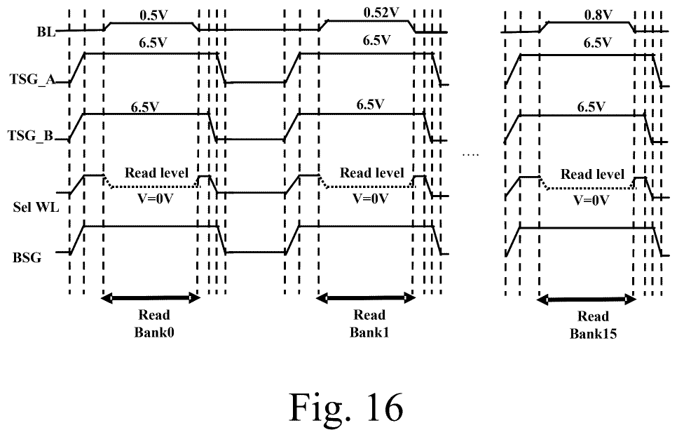

FIG. 16 is an operation timing diagram of a semiconductor device according to an example of the present disclosure. For case of understanding, the following will take 16 memory banks being coupled to a bit line as an example for illustration. FIG. 16 shows memory banks Bank0 to Bank15 arranged sequentially along the direction from the first end of the bit line pointing to the second end. Referring to FIG. 16, during the read stage of memory bank Bank0, the voltage applied to the bit line is 0.5V, and during the read stage of memory bank Bank1, the voltage applied to the bit line is 0.52V, . . . , and during the read stage of memory bank Bank15, the voltage applied to the bit line is 0.8V. In such a way, the difference in bit line voltage drops among a plurality of memory banks coupled to the same bit line may be compensated, therefore improving the accuracy of computing-in-memory. Here, during the read stages of different memory banks, the voltages applied to the upper select line TSGA, upper select line TSGB, selected word line Sel WL, and lower select line BSG may remain unchanged, as shown in FIG. 16.

Based on the above semiconductor devices, an example of the present disclosure provides a system including: at least one semiconductor device of any one of the above examples; and a controller coupled to the semiconductor device. The controller is configured to send input data to the semiconductor device and receive the operation results of the semiconductor device.

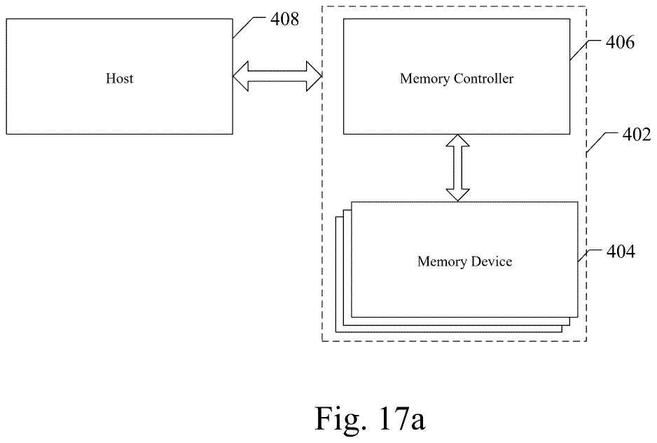

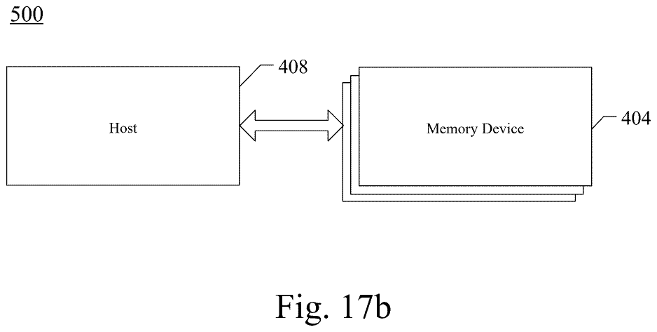

In some examples, the system in the above examples may include the memory system 402 as shown in FIG. 17a, which includes a memory controller 406 and a memory device 404 coupled to the memory controller 406. The memory controller 406 may include a graphics processing unit (GPU), and the memory device 404 may include the semiconductor device 200 in the above examples. The GPU in the memory controller 406 may control the memory device 404 to perform parallel computing.

According to some examples, as shown in FIG. 17a, the memory controller 406 is coupled to the memory device 404 and the host 408, and is configured to control operations of the memory device 404, such as read, erase, program, and compute operations. The memory controller 406 may manage data stored in the memory device 404 and communicate with the host 408.

In some other examples, the system in the above examples may be the system 500 shown in FIG. 7b, which includes a host 408 and a memory device 404 coupled to the host 408. The host 408 may include a GPU, and the memory device 404 may include the semiconductor device 200 in the above examples. The GPU in the host 408 may control the memory device 404 to perform parallel computing.

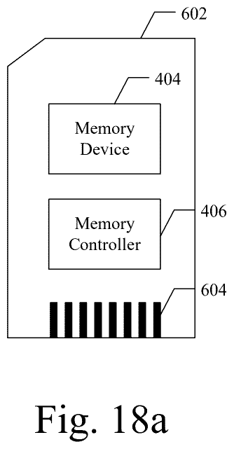

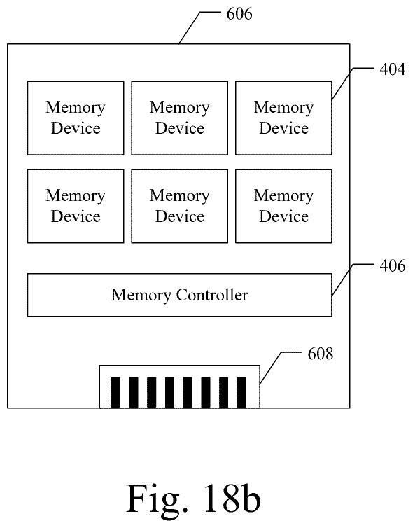

In an example shown in FIG. 18a, the system may be integrated into memory card 602. The semiconductor device in the system may include memory device 404 in memory card 602, and the controller in the system may include memory controller 406 in memory card 602. The memory card 602 may include one of a compact flash card, a Smart Media Card (SMC), a Memory Stick (MS), a Multi Media Card (MMC) such as RS-MMC, MMCmicro, eMMC, etc., a secure digital card such as Mini SD card, Micro SD card, SDHC card, etc., and a universal flash card. The memory card 602 may also include a memory card connector 604 that couples the memory card 602 with the host. In another example shown in FIG. 18b, the system may be integrated into a Solid State Disk (SSD) 606. The semiconductor device in the system may include the memory device 404 in the SSD 606, and the controller in the system may include the memory controller 406 in the SSD 606. The solid-state disk 606 may also include a solid-state disk connector 608 that couples the solid-state disk 606 with the host device. In some implementations, the storage capacity and/or operating speed of the solid-state disk 606 is greater than the storage capacity and/or operating speed of the memory card 602.

In some other examples, the system may be integrated into a terminal device, and the controller may include the central processing unit (CPU) of the terminal device. Here, the terminal device may include but is not limited to a mobile phone, a smart TV, a smart stereo, a wearable device, a tablet computer, a desktop computer, an all-in-one computer, a handheld computer, a notebook, a server, a Ultra Mobile Personal Computer (UMPC), a netbook, a Personal Digital Assistant (PDA), a laptop, a mobile computer, an Augmented Reality (AR) device, a Virtual Reality (VR) device, an Artificial Intelligence (AI) device, etc. or any terminal device or portable terminal device.

In some examples, the system may be configured to implement various complex algorithms and data processing tasks. In an example, the system may be configured in the field of artificial intelligence, such as machine learning, deep learning, neural network, convolutional neural network, and so on.

Based on the above semiconductor device and method of operating it, an example of the present disclosure provides a computer-readable storage medium with a computer program stored thereon, when executed by a processor, the computer program implements the method of any of the above examples.

Here, the implementation of the process of all or part of the methods in the above examples may be completed by instructing relevant hardware by a computer program. The computer program may be stored in a computer-readable storage medium, and when executed, may include the flow of the examples of the above methods. The storage medium may be Ferromagnetic Random Access Memory (FRAM), Read Only Memory (ROM), Programmable Read Only Memory (PROM), Erasable Programmable Read Only Memory (EPROM), Electrically Erasable Programmable Read Only Memory (EEPROM), Flash Memory, Magnetic Surface Memory, Compact Disc or Compact Disc Read Only Memory (CD-ROM), etc. The storage medium may also include a combination of the above-mentioned types of memory.

The features disclosed in the several device examples provided in the present disclosure may be combined arbitrarily without conflict to obtain a new device example.

The methods disclosed in the several method examples provided in the present disclosure may be combined arbitrarily without conflict to obtain a new method example.

It should be understood that the term “one example” or “an example” mentioned throughout the specification means that specific features, structures, or characteristics related to the example are included in at least one example of the present disclosure. Therefore, the term “in one example” or “in an example” that appear throughout the specification may not necessarily refer to the same example. In addition, these specific features, structures, or characteristics may be combined in one or more examples in any suitable manner. It should be understood that in the various examples of the present disclosure, the size of the sequence numbers of the above processes does not imply the order of execution. The order of execution of each process should be determined by its function and internal logic, and should not constitute any limitation on the implementation process of the disclosed examples. The above disclosed examples are numbered for description only and do not represent the advantages or disadvantages of the examples.

It should be noted that herein, the terms “comprise”, “include” or any other variation thereof are intended to encompass non-exclusive inclusion, such that a process, method, subject, or apparatus that includes a series of elements not only includes those elements, but also includes other elements not explicitly listed, or also includes elements inherent to such process, method, subject, or apparatus. Without further limitations, the element limited by the statement “including one . . . ” does not exclude the existence of other identical elements in the process, method, subject, or apparatus that includes that element.

The above are only examples of the present disclosure, and the scope of the present disclosure is not limited to this. Variations or alternatives conceivable to any skilled person in the art within the scope disclosed in the present disclosure should be included in the scope of the present disclosure.

What is claimed is:

1. A semiconductor device, comprising:
a plurality of memory banks; and
a peripheral circuit coupled to the plurality of memory banks through a bit line and configured to:
provide a first voltage to the bit line and sense a current on the bit line during a first read stage of a first memory bank of the plurality of memory banks; and
provide a second voltage to the bit line and sense a current on the bit line during a second read stage of a second memory bank of the plurality of memory banks, wherein
the first memory bank and the second memory bank are arranged along a direction from a first end of the bit line pointing to a second end of the bit line, the first end is a node where the bit line is coupled to a page buffer or a bit line driver, the second read stage is different from the first read stage, and the second voltage is greater than the first voltage, and/or a sense duration of the second read stage is greater than a sense duration of the first read stage.

2. The semiconductor device of claim 1, wherein the peripheral circuit comprises:
a voltage generation circuit configured to generate an initial voltage, wherein the initial voltage is greater than or equal to the second voltage; and
a voltage regulation circuit coupled to the voltage generation circuit and the bit line, respectively, and configured to:
regulate the initial voltage to the first voltage during the first read stage; and
regulate the initial voltage to the second voltage during the second read stage.

3. The semiconductor device of claim 2, wherein the voltage regulation circuit includes a variable resistor.

4. The semiconductor device of claim 1, wherein the peripheral circuit comprises:
a voltage generation circuit coupled to the bit line and configured to:
generate the first voltage during the first read stage; and
generate the second voltage during the second read stage.

5. The semiconductor device of claim 1, wherein in a case where the sense duration of the second read stage is greater than the sense duration of the first read stage, a first reference current corresponding to the first read stage is greater than a second reference current corresponding to the second read stage.

6. The semiconductor device of claim 5, wherein the peripheral circuit is further configured to:
generate a first read result based on a sensed current on the bit line during the first read stage and the first reference current; and
generate a second read result based on a sensed current on the bit line during the second read stage and the second reference current.

7. The semiconductor device of claim 1, wherein the plurality of memory banks coupled to the bit line form a plurality of memory bank groups, wherein the first memory bank and the second memory bank are in different memory bank groups, respectively.

8. The semiconductor device of claim 1, wherein the plurality of memory banks coupled to the bit line form a plurality of memory bank groups, wherein the first memory bank and the second memory bank are in the same memory bank group.

9. The semiconductor device of claim 1, wherein the peripheral circuit is further configured to:
apply corresponding input voltages to a plurality of first selection lines coupled to the first memory bank during the first read stage respectively; and
apply corresponding input voltages to a plurality of second selection lines coupled to the second memory bank during the second read stage respectively.

10. The semiconductor device of claim 1, wherein the semiconductor device comprises a three-dimensional NAND memory device.

11. A method of operating a semiconductor device, comprising:
providing a first voltage to a bit line coupled to a plurality of memory banks and sensing a current on the bit line during a first read stage of a first memory bank of the plurality of memory banks; and
providing a second voltage to the bit line and sensing a current on the bit line during a second read stage of a second memory bank of the plurality of memory banks, wherein
the first memory bank and the second memory bank are arranged along a direction from a first end of the bit line pointing to a second end of the bit line, the first end is a node where the bit line is coupled to a page buffer or a bit line driver, the second read stage is different from the first read stage, and the second voltage is greater than the first voltage, and/or a sense duration of the second read stage is greater than a sense duration of the first read stage.

12. The method of claim 11, further comprising:
generating an initial voltage, wherein the initial voltage is greater than or equal to the second voltage;
regulating the initial voltage to the first voltage during the first read stage; and
regulating the initial voltage to the second voltage during the second read stage.

13. The method of claim 11, further comprising:
generating the first voltage during the first read stage; and
generating the second voltage during the second read stage.

14. The method of claim 11, wherein in a case where the sense duration of the second read stage is greater than the sense duration of the first read stage, a first reference current corresponding to the first read stage is greater than a second reference current corresponding to the second read stage.

15. The method of claim 14, further comprising:
generating a first read result based on a sensed current on the bit line during the first read stage and the first reference current; and
generating a second read result based on a sensed current on the bit line during the second read stage and the second reference current.

16. The method of claim 11, wherein the plurality of memory banks coupled to the bit line form a plurality of memory bank groups, wherein the first memory bank and the second memory bank are in different memory bank groups, respectively.

17. The method of claim 11, wherein the plurality of memory banks coupled to the bit line form a plurality of memory bank groups, wherein the first memory bank and the second memory bank are in the same memory bank group.

18. The method of claim 11, further comprising:
applying corresponding input voltages to a plurality of first selection lines coupled to the first memory bank during the first read stage respectively; and
applying corresponding input voltages to a plurality of second selection lines coupled to the second memory bank during the second read stage respectively.

19. A system, comprising:
at least one semiconductor device, comprising:
a plurality of memory banks; and
a peripheral circuit coupled to the plurality of memory banks through a bit line and configured to:
provide a first voltage to the bit line and sense a current on the bit line during a first read stage of a first memory bank of the plurality of memory banks; and
provide a second voltage to the bit line and sense a current on the bit line during a second read stage of a second memory bank of the plurality of memory banks, wherein
the first memory bank and the second memory bank are arranged along a direction from a first end of the bit line pointing to a second end of the bit line, the first end is a node where the bit line is coupled to a page buffer or a bit line driver, the second read stage is different from the first read stage, and the second voltage is greater than the first voltage, and/or a sense duration of the second read stage is greater than sense duration of the first read stage; and
a controller coupled to the semiconductor device and configured to send input data to the semiconductor device and receive an operation result of the semiconductor device.

20. The system of claim 19, wherein the peripheral circuit comprises:
a voltage generation circuit configured to generate an initial voltage, wherein the initial voltage is greater than or equal to the second voltage; and
a voltage regulation circuit coupled to the voltage generation circuit and the bit line, respectively, and configured to:
regulate the initial voltage to the first voltage during the first read stage; and
regulate the initial voltage to the second voltage during the second read stage.
